(19) United States
(12) Patent Application Publication
(10) Pub. No.: US 2006/0108665 A1
(43) Pub. Date: May 25, 2006

(54) Semiconductor device, manufacturing method of the same, and electronic device

(76) Inventors: Atsushi Kurokawa, Takasaki (JP); Yasunari Umemoto, Sayama (JP); Satoshi Sasaki, Takasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/283,922

(22) Filed: Nov. 22, 2005

(30) Foreign Application Priority Data
Nov. 22, 2004 (JP) 2004-337198

(51) Int. Cl. H01L 31/11; H01L 27/082

(52) U.S. Cl. 257/592

(57) ABSTRACT

The invention is directed to improve characteristics of an HBT (Hetero-junction Bipolar Transistor). An HBT has a collector layer, a base layer, and an emitter layer formed in order on a main surface of a substrate made of a compound semiconductor and a collector electrode, a base electrode, and an emitter electrode electrically connected to the collector layer, the base layer, and the emitter layer, respectively, and further has an emitter contact layer formed between the emitter electrode and the emitter layer. The plane shape of the emitter contact layer and the emitter electrode is an almost annular shape surrounding the base electrode in a plane parallel with the main surface of the substrate, and the lower limit of the emitter contact layer is 1.2 μm or larger.

### CROSS-REFERENCE TO RELATED APPLICATION

The present application claims priority from Japanese patent application No 2004-337198 filed on Nov. 22, 2004, the content of which is hereby incorporated by reference into this application.

### BACKGROUND OF THE INVENTION

The present invention relates to a semiconductor device and a technique of manufacturing the same. More particularly, the invention relates to a technique effective when applied to a hetero-junction bipolar transistor (hereinbelow, called HBT) and to an electronic device using the same HBT.

As one of bipolar transistors in each of which a collector layer, a base layer, and an emitter layer are sequentially formed on a substrate (semiconductor substrate) made of a compound semiconductor such as GaAs, a mesa transistor (mesa junction bipolar transistor) having a trapezoidal shape in cross section and whose surface in which an emitter and a base are formed is smaller than that of the substrate is known. Since a junction surface of the mesa transistor is a flat surface, a withstand voltage higher than that of a planar junction can be obtained, and the junction area and the capacitance are smaller. Thus, high frequency performance can be improved.

On the other hand, in an HBT using different semiconductor materials for the emitter layer and the base layer (for example, AlGaAs/GaAs, InGaP/GaAs, or the like) as one of bipolar transistors, leakage of holes to the emitter layer can be suppressed by a barrier of the interface between the emitter layer and the base layer. Consequently, the collector current can be increased without decreasing the current amplification factor. By reducing the thickness of the base layer, travel time of electrons is shortened, so that the response speed of the transistor increases, that is, the high frequency operation can be performed. The HBT has characteristics adapted to a high frequency power amplifier performing heavy-current and high-frequency operation, a semiconductor device such as a power amplifier module, and an electrode device. To improve the performance of a power amplifier, particularly, power added efficiency, power gain, and the like, it is essential to reduce the base-collector junction capacitance per unit area.

In the HBT having a base mesa and an emitter mesa, the ratio of the base-collector junction area in the emitter-base junction area has to be reduced. Specifically, the base-collector junction area of the base mesa has to be made smaller than the emitter-base junction area of the emitter mesa.

Japanese Unexamined Patent Publication No. 2002-246587 discloses a method of employing a layout in which the plane shape of a base layer and an emitter layer in an HBT is a circular shape in order to reduce the area ratio of the base mesa region in the emitter area.

### SUMMARY OF THE INVENTION

The inventors of the present invention have examined an HBT in which a base electrode has a circular shape and an emitter electrode has an annular shape. FIG. 29 is a plan view showing a main part of a semiconductor device having the HBT examined by the inventors herein. Shown in the diagram are an HBT 51, a base electrode 52, an emitter electrode 53, a lower limit 53D of the emitter electrode, a collector electrode 54, a first layer line 55 (shown by a broken line), a second layer line 56, and a contact hole 57 for the emitter. In the HBT 51, the base electrode 52 is formed in a circular shape to reduce its area and, in addition, the emitter electrode 53 is formed in an almost annular shape, thereby reducing the ratio of the base-collector junction area in the emitter area to be very low. Thus, the capacitance between the base and the collector becomes very small, and high gain and high efficiency can be realized.

In the HBT 51 including the emitter electrode 53 having an almost annular shape, however, the base electrode 52 is connected to a base lead line formed by the first layer line 55, and the emitter electrode 53 is connected to an emitter lead line formed by the second layer line 56. Consequently, the first layer line 55 just above the emitter electrode 53 becomes an obstacle and the contact hole 57 for the emitter cannot be provided on the entire surface of the emitter electrode 53. As a result, dissipation of heat generated in the emitter region below the emitter electrode 53 via the lead wiring (second layer line 56) extended to the emitter electrode 53 is suppressed. When the HBT 51 is operated by energizing, the temperature of the emitter electrode 53 rises locally (in particular, the regions surrounded by relatively-thick alternate long and short dash lines), the characteristic deterioration is accelerated, and a problem occurs such that the life of the HBT 51 at the time of operation (energizing) test is shortened. In particular, in the case where the process of manufacturing the HBT 51 includes an etching process using the emitter electrode 53 as a mask, WSi (tungsten silicide) effective as a mask is generally used for the emitter electrode 53. However, since the thermal conductivity of WSi is relatively low, local temperature rise in the emitter electrode 53 made of WSi is a serious problem.

Consequently, the inventors herein have examined a method of reducing the lower limit 53D of the emitter electrode 53 to thereby reduce the emitter region below the base lead line made by the first layer line 55 as much as possible. It was, however, found that when the emitter region below the base lead wiring made by the first layer wiring 55 is reduced too much, at the time of operating the HBT 51, a problem occurs such that the current amplification h_{FE} of low current of the HBT 51 tends to drop and reliability becomes poor.

An object of the invention is to provide a technique for improving the characteristics of a bipolar transistor.

The above and other objects and novel features of the invention will become apparent from the description of the specification and the appended drawings.

An outline of a representative one of inventions disclosed in the application will be briefly described as follows.

A semiconductor device according to the present invention includes a bipolar transistor comprising: a substrate made of a compound semiconductor; a collector layer formed on a main surface of the substrate; a base layer formed on the collector layer; an emitter layer formed on the base layer; a collector electrode electrically connected to the collector layer; a base electrode electrically connected to the base layer; an emitter contact layer formed on the emitter layer and electrically connected to the emitter layer; and an emitter electrode electrically connected to the emitter contact layer. A plane shape of the base layer is an almost circular shape in a plane parallel with the main surface of the substrate, a plane shape of the emitter layer, the emitter contact layer, and the emitter electrode is an almost annular shape surrounding the base electrode in a plane parallel with the main surface of the substrate, and lower limit of the emitter contact layer is 1.2 μm or larger in a direction parallel with the main surface of the substrate.

An effect obtained by the representative one of the inventions disclosed in the application will be briefly described as follows.

By optimizing the lower limit of the emitter contact layer in the direction parallel with the main surface of a semiconductor substrate, the characteristics of the bipolar transistor can be improved.

### BRIEF DESCRIPTION OF THE DRAWINGS

FIG. 1 is a plan view showing an example of a semiconductor device in a first embodiment of the invention.

FIG. 2 is a cross section taken along line A-A′ of the semiconductor device illustrated in FIG. 1.

FIG. 3 is a cross section taken along line B-B′ of the semiconductor device illustrated in FIG. 1.

FIG. 4 is a plan view showing an example of the semiconductor device in the first embodiment of the invention.

FIG. 5 is a diagram illustrating characteristics of the semiconductor device in the first embodiment of the invention.

FIG. 6 is a diagram illustrating characteristics of the semiconductor device in the first embodiment of the invention.

FIG. 7 is a cross section of a main part of the semiconductor device shown in FIG. 3.

FIG. 8 is a diagram illustrating characteristics of the semiconductor device in the first embodiment of the invention.

FIG. 9 is a plan view showing an example of the semiconductor device in the first embodiment of the invention.

FIG. 10 is a plan view showing an example of the semiconductor device in the first embodiment of the invention.

FIG. 11 is a plan view showing an example of the semiconductor device in the first embodiment of the invention.

FIG. 12 is a cross section of a main part illustrating a method of manufacturing the semiconductor device in the first embodiment of the invention.

FIG. 13 is a cross section of a main part in a semiconductor device manufacturing process subsequent to FIG. 12.

FIG. 14 is a cross section showing a main part in a semiconductor device manufacturing process subsequent to FIG. 13.

FIG. 15 is a cross section of a main part in a semiconductor device manufacturing process subsequent to FIG. 14.

FIG. 16 is a cross section showing a main part in a semiconductor device manufacturing process subsequent to FIG. 15.

FIG. 17 is a cross section of a main part in a semiconductor device manufacturing process subsequent to FIG. 16.

FIG. 18 is a cross section showing a main part in a semiconductor device manufacturing process subsequent to FIG. 17.

FIG. 19 is a cross section of a main part in a semiconductor device manufacturing process subsequent to FIG. 18.

FIG. 20 is a cross section showing a main part in a semiconductor device manufacturing process subsequent to FIG. 19.

FIG. 21 is a plan view of a main part illustrating a method of manufacturing the semiconductor device shown in FIG. 20.

FIG. 22 is a cross section of a main part in a semiconductor device manufacturing process subsequent to FIG. 20.

FIG. 23 is a plan view of a main part illustrating a method of manufacturing the semiconductor device shown in FIG. 22.

FIG. 24 is a plan view of a main part illustrating a method of manufacturing the semiconductor device shown in FIG. 22.

FIG. 25 is a cross section of a main part in a semiconductor device manufacturing process subsequent to FIG. 22.

FIG. 26 is a plan view of a main part of an electronic device in a second embodiment of the invention.

FIG. 27 is a plan view of a main part of a semiconductor chip illustrated in FIG. 26.

FIG. 28 is a circuit diagram of a main part of the electronic device illustrated in FIG. 26.

FIG. 29 is a plan view showing a semiconductor device examined by the inventors of the present invention.

### DETAILED DESCRIPTION OF THE PREFERRED EMBODIMENTS OF THE INVENTION

Embodiments of the invention will be described in detail hereinbelow. In all of the diagrams illustrating the embodiments, the same reference numeral is given to the same member as a rule and its repetitive description will not be given.

### First Embodiment

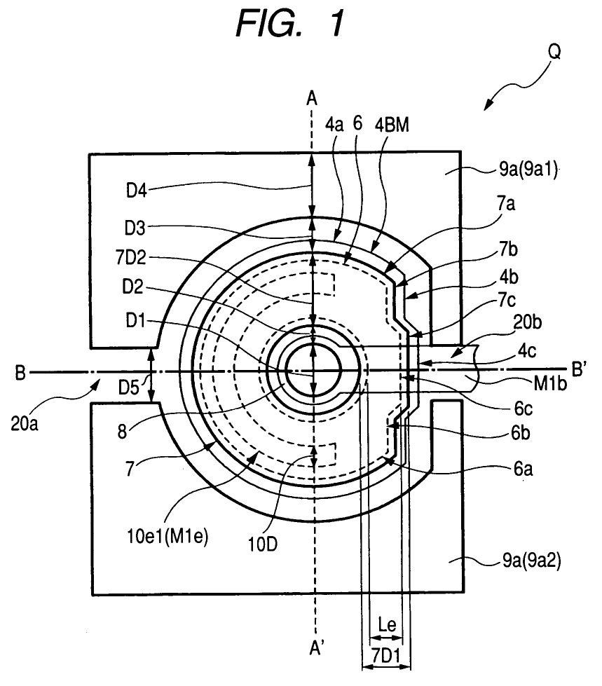

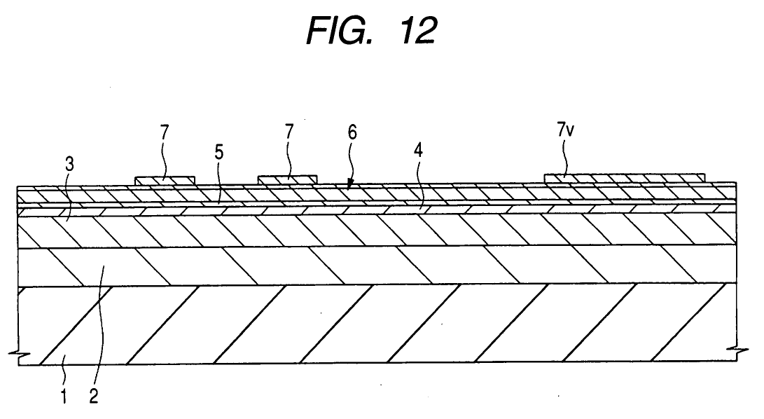

An example of a semiconductor device including a hetero-junction bipolar transistor (HBT) as a first embodiment will be described by referring to FIGS. 1 to 25. Briefly, the structure of an HBT in the embodiment will be described first with reference to FIGS. 1 to 11 and, after that, a method of manufacturing a semiconductor device including the HBT will be described with reference to FIGS. 12 to 25.

First, the structure of a semiconductor device including an HBT of the embodiment will be described. FIG. 1 is a plan view showing an example of an HBT(Q) of the embodiment and shows a layout of a base electrode 8, an emitter electrode 7, a collector electrode 9a, a base mesa 4BM, an emitter contact layer 6, a contact hole 10e1, and a base lead line M1b of an HBT(Q) formed on a substrate. The layout is in a plane parallel with the main surface of the substrate where the HBT(Q) is formed.

As shown in FIG. 1, in the HBT(Q), the base electrode 8 is disposed, the emitter electrode 7 is disposed so as to surround the base electrode 8 as a center, and the collector electrode 9a is disposed so as to surround the emitter electrode 7. The plane shape (plane pattern) of the base electrode 8 is a circular shape. The plane shape of the emitter electrode 7 is an almost annular shape surrounding the base electrode 8, and its outer periphery is constructed by an arc 7a, a chord 7b, and a projection 7c connected to the chord 7b.

The collector electrode 9a does not have a shape completely surrounding the periphery of the emitter electrode 7 but is constructed by a pair of a first part 9a1 and a second part 9a2 separated by two notches 20a and 20b. The plane shape of each of the first and second parts 9a1 and 9a2 is an almost C shape. The notches 20a and 20b are disposed almost symmetrical with respect to the base electrode 8 but do not have to be always in opposite positions, that is, on both sides of the center of an area where the HBT(Q) is formed. It is sufficient that, for example, the angle formed by the two notches and a line connecting the center of the HBT formation area is 90 degrees or higher. Alternately, two or more notches may be provided.

As shown in FIG. 1, by arranging one of the two notches 20a and 20b on the chord 7b or the projection 7c side of the emitter electrode 7, formation of the base lead line M1b is facilitated. In addition, parasitic capacitance between the base lead line M1b and a collector lead line electrically connected to the collector electrode 9a can be reduced.

The emitter contact layer 6 is formed below the emitter electrode 7, and the base mesa 4BM is formed below the base electrode 8 and the emitter electrode 7. The contact hole 10e1 for the emitter is formed in the periphery of the base electrode 8 and along the arc 7a of the emitter electrode 7.

The plane shape of the emitter contact layer 6 becomes similar to that of the emitter electrode 7 since the forming method is the wet etching technique using the emitter electrode 7 as a mask. Therefore, the plane shape of the emitter contact layer 6 is almost an annular shape surrounding the base electrode 8, and its outer periphery is constructed by an arc 6a, a chord 6b, and a projection 6c connected to the chord 6b. The plane shape of the base mesa 4BM is almost circular by the forming method that is photolithography and wet etching technique, and it outer periphery is constructed by an arc 4a, a chord 4b, and a projection 4c connected to the chord 4b. Although not shown, an emitter layer surrounding the base electrode 8 is formed between the emitter contact layer 6 and the base mesa 4BM in the thickness direction of a substrate. The plane shape of the emitter layer is an almost annular shape and its outer periphery is constructed by an arc, a chord, and a projection connected to the chord.

The contact hole 10e1 for the emitter is formed along the arc 7a on the emitter electrode 7 so that an emitter lead line M1e electrically connected to the emitter electrode 7 is formed in the contact hole 10e1. The contact hole 10e1 for the emitter is formed in the periphery of the contact hole for the base (for the base lead line M1b). The plane shape of the contact hole 10e1 for the emitter is a C shape having a width of a dimension 10D.

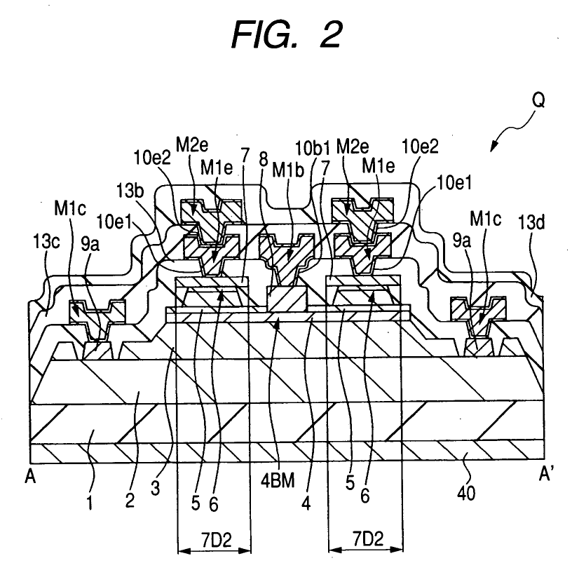

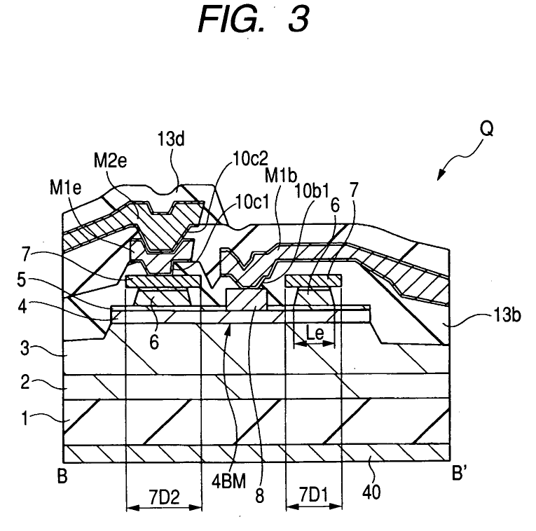

The base lead wiring M1b is electrically connected to the base electrode 8 and extends so as to pass above the chord 7b or the projection 7c of the emitter electrode 7. The base lead line M1b and the emitter lead line M1e are formed by the same layer line (refer to FIGS. 2 and 3 to be described later).

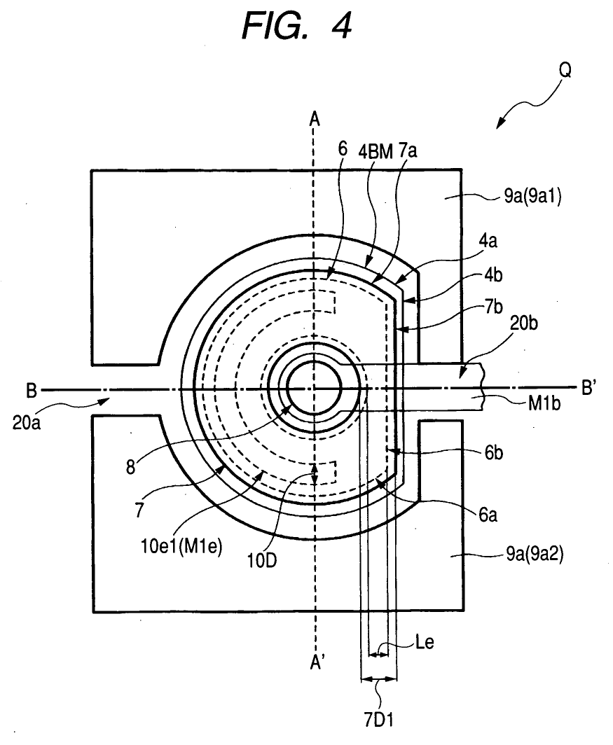

Examples of concrete design dimensions will be described below. A dimension 7D1 of the emitter electrode 7 in the direction crossing the base lead line M1b is 2.0 μm, a dimension D1 of the diameter of the base electrode 8 is 2.0 μm, a dimension D2 between the base electrode 8 and the emitter electrode 7 is 1.5 μm. A dimension 7D2 of the width of the annular part (arc 7a) of the emitter electrode 7 is 4.0 μm, a dimension D3 between the emitter electrode 7 and the collector electrode 9a is 2.0 μm, and a dimension of the width in the direction perpendicular to the base lead line M1b of the collector electrode 9a is 4.5 μm. A dimension D5 of the width in the direction perpendicular to the base lead line M1b of the notches 20a and 20b is 4.5 μm. The dimension 7D1 is the smallest dimension (lower limit) of the inner circumference and the outer circumference of the emitter electrode 7 whose plane shape is an almost annular shape. On the other hand, the dimension 7D2 is the largest dimension (upper limit). Le in the diagram is the lower limit of the emitter contact layer 6, and the design dimension of the lower limit Le is, for example, 1.4 μm. In the HBT(Q) shown in FIG. 1, the lower limit Le falls on the projection 6c connected to the chord 6b of the emitter contact layer 6. In an HBT(Q) in which the projection 6c is not connected, for example, an HBT (Q) shown in FIG. 4 to be described later, the lower limit Le falls on the chord 6b.

FIG. 2 is a cross section taken along line A-A′ of FIG. 1, and FIG. 3 is a cross section taken along line B-B′ of FIG. 1. Since the structure will become clearer by the following description of the manufacturing method, characteristic configurations will be described here.

As shown in FIGS. 2 and 3, an HBT(Q) is formed on a main surface of a substrate 1 made of a compound semiconductor such as GaAs (gallium arsenide), and a back-side electrode 40 is formed on the back side of the substrate 1.

On the main surface of the substrate 1, a sub-collector layer 2 made of n⁺-type GaAs, a collector layer 3 made of n-type GaAs, a base layer 4 made of p-type GaAs, and an emitter layer 5 made of n-type InGaP (indium gallium phosphide) or n-type AlGaAs (aluminum gallium arsenide) are sequentially formed. The collector layer 3 made of n-type GaAs and the sub-collector layer 2 made of n⁺-type GaAs can be considered as a collector layer. The portion having a trapezoidal cross section of the junction part between the collector layer 3 and the base layer 4 is the base mesa 4BM. In the embodiment, it is assumed that the base mesa 4BM includes the base layer 4.

The collector electrode 9a is formed around the base mesa 4BM and electrically connected to the collector layer 3. A collector lead line M1c electrically connects the collector electrode 9a made by the pair of the first part 9a1 and the second part 9a2 shown in FIG. 1.

The base electrode 8 electrically connected to the base layer 4 is formed in the center portion of the base mesa 4BM, and the emitter contact layer 6 and the emitter electrode 7 are formed so as to surround the base electrode 8 on the emitter layer 5 made of n-type InGaP. The emitter contact layer 6 is formed on the emitter layer 5 and is electrically connected to the emitter layer 5. The emitter electrode 7 is formed on the emitter contact layer 6 and is electrically connected to the emitter contact layer 6.

The emitter contact layer 6 is made of n-type GaAs and n-type InGaAs (indium gallium arsenide), and the n-type InGaAs is used to form an ohmic contact with the emitter electrode 7. In some cases, the emitter contact layer 6 is made of only n-type GaAs. As shown in FIGS. 2 and 3, the emitter contact layer 6 having a trapezoidal shape in section is so-called emitter mesa, and the dimension below the emitter contact layer 6 on the emitter layer 5 side becomes the emitter mesa width. The lower limit of the emitter mesa width is the lower limit Le of the emitter contact layer 6.

On the emitter electrode 7 and the base electrode 8, insulating films (interlayer insulating layers) 13b, 13c, and 13d such as silicon oxide films are formed. A contact hole 10e1 for the emitter and a contact hole 10b1 for the base are formed in the interlayer insulating film 13b. The emitter lead line M1e and the base lead line M1b electrically connected to the emitter electrode 7 and the base electrode 8 are formed via the contact hole 10e1 for the emitter and the contact hole 10b1 for the base, respectively.

As shown in FIG. 3, the base lead line M1b connected to the base electrode 8 is led (extends) over the emitter electrode 7 to the outside of the base mesa 4BM. Consequently, it is understood that, over the emitter electrode 7 below the base lead line M1b, the contact hole 10e1 and the emitter lead electrode M1e of the first layer line cannot be formed and further, the contact hole 10e2 and the emitter lead line M2e of the second layer line as upper layers cannot be also formed. Therefore, the emitter lead lines M1e and M2e having the role of dissipating heat generated from the emitter region cannot be formed and, in the emitter region below the base lead line M1b, temperature becomes higher than that of the emitter region other than the region below the base lead line M1b. Heat in the emitter region is generated in a process in which electrons injected from the emitter electrode 7 at the time of operation of the HBT(Q) pass through the emitter contact layer 6, emitter layer 5, and base layer 4 and reach the collector layer 3.

The inventors herein also have examined an HBT(Q) in which the area of the emitter region below the base lead line M1b is reduced as much as possible, an almost annular shape is used as the plane shape of the emitter contact layer 6 as shown in FIG. 4 in order to moderate the heat generation, and the outer circumference is constructed by the arc 6a and the chord 6b. That is, the inventors herein formed an HBT(Q) by reducing the lower limit Le of the emitter contact layer 6 in order to decrease the area of the emitter region below the base lead line M1b. As shown in FIG. 4, in a plane parallel with the main surface of the substrate in which the HBT (Q) is formed, the outer circumference of each of the base mesa 4BM (base layer 4), the emitter layer 5 (not shown), the emitter contact layer 6, and the emitter electrode 7 of the HBT(Q) has a plane shape constructed by an arc and a chord without the projection as shown in FIG. 1.

However, in the case where the lower limit Le of the emitter contact layer 6 is reduced to, for example, 1.0 μm, a problem occurs such that the current amplification h_{FE} of low current when the HBT is operated tends to decrease and the reliability tends to be poor. To solve the problem, the inventors conducted a study to be described below and found that there is a correlation between the low limit Le of the emitter contact layer 6 and the rate of decrease of the current amplification h_{FE}. Consequently, by optimizing the lower limit Le of the emitter contact layer 6, the characteristics of the HBT(Q) can be improved.

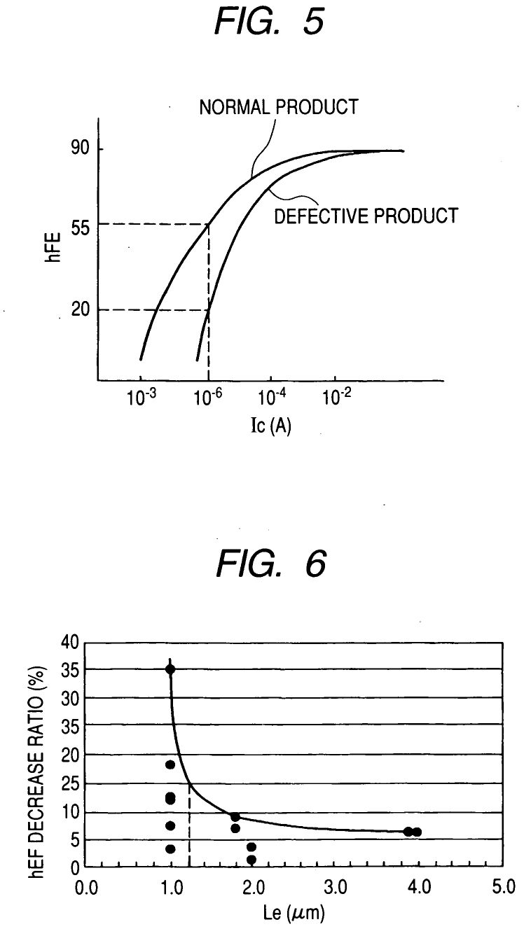

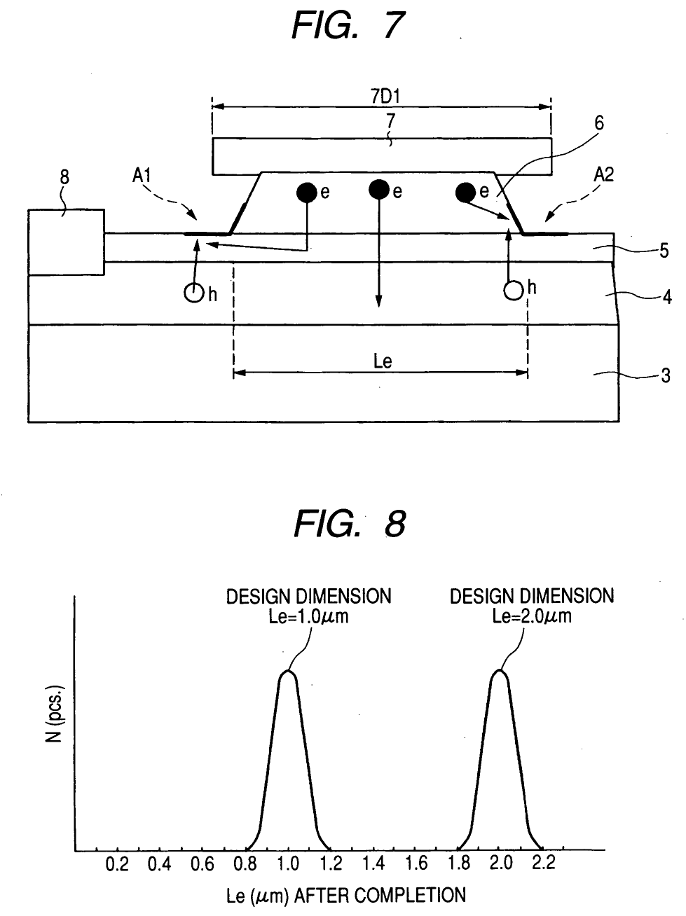

FIG. 5 is a diagram illustrating the correlation between the current amplification h_{FE} and the collector current Ic. FIG. 6 is a diagram illustrating the correlation between the lower limit Le of the emitter contact layer 6 of design dimension and h_{FE} decrease ratio. FIG. 7 is an enlarged cross section of a main part of FIG. 3. FIG. 8 is a distribution diagram of lower limits Le after completion at the time of design dimensions of 1.0 μm and 2.0 μm.

First, the h_{FE} decrease ratio is a decrease ratio of h_{FE} of a defective HBT (the ratio of h_{FE}) to that of a normal (average) HBT in the collector current Ic of 10⁻⁶ A as low current in the case where the HBT is operated as shown in FIG. 5. The area of the emitter in the HBT is about 100 μm², and a collector-emitter voltage VCE of the HBT is about 3.5V.

Therefore, for example, in the case of operating the HBT when the design dimension of the lower limit Le of the emitter contact layer 6 is set to about 1.0 μm, h_{FE} of an operation normal product is 55 and that of a defective product is 20, so that the decrease ratio of h_{FE} at the collector current Ic of 10⁻⁶ A (low current) is 35%. When a reliability test was conducted on an HBT having the h_{FE} decrease ratio of 35%, reliability was poor.

It is understood from FIG. 6 that, in the case of operating HBTs formed with various design dimensions of the lower limit Le of the emitter contact layer 6, the h_{FE} decrease ratio at the collector current Ic of 10⁻⁶ A (low current) increases as the lower limit Le of the emitter contact layer 6 decreases from about 4.0 μm to about 1.0 μm.

The cause that the h_{FE} decrease ratio increases as the lower limit Le of the emitter contact layer 6 decreases will be described by using FIG. 7. Electrons (e) are injected from the emitter electrode 7, normally, pass through the base layer 4, and reach the collector layer 3 (heat generation also occurs in the emitter region). In some cases, the electron (e) injected from the emitter electrode 7 and a hole (h) in the base layer 4 are re-combined around the surface of the emitter layer 5 as the interface between the emitter layer 5 and the emitter contact layer 6 and the surface of the emitter contact layer as the interface between the emitter layer 5 and the emitter contact layer 6. In particular, as shown in FIG. 7, the recombination is more active in regions A1 and A2 (indicated by thick lines) around the surfaces of the emitter contact layer 6 and the emitter layer 5 etched to form the emitter contact layer 6. Specifically, recombination occurs at a surface trap level in the n-type InGaP of the emitter layer 5 and the n-type GaAs of the emitter contact layer 6 in the regions A1 and A2, and h_{FE} decreases due to recombination current in the regions A1 and A2. It is therefore considered that when the lower limit Le of the emitter contact layer 6 decreases, the surface recombination current becomes relatively large and a sharp drop occurs in h_{FE}. As another factor, an increase in the surface trap level caused by adhesion of metal impurity to the surface of crystal immediately after process (formation) of the emitter contact layer 6 can be also considered. An increase in recombination in a region in the emitter layer 5 caused by electrons entered from the region A1 due to diffusion of metal impurity under certain circumstances can be also considered.

It is understood from the above consideration that, in the case of operating an HBT, the larger the lower limit Le of the emitter contact layer 6 is, the more the h_{FE} decrease ratio accompanying lapse of time at the time of low current can be suppressed. However, when the lower limit Le of the emitter contact layer 6 is large, the emitter region becomes larger. Consequently, heat generation in the emitter region increases, that is, thermal resistance of the HBT increases. It is therefore necessary to optimize the lower limit Le of the emitter contact layer 6 so that the decrease ratio of h_{FE} that decreases with lapse of time at the time of low current and the thermal resistance can be suppressed. HBT operation tests and reliability tests were conducted while variously changing the lower limit Le of the emitter contact layer 6 and it was found that there is no problem when the h_{FE} decrease ratio is 15% or less. It was consequently found from FIG. 6 that the lower limit Le of the emitter contact layer 6 when the h_{FE} decrease ratio is 15% or less is about 1.2 μm.

On the other hand, as shown in FIG. 8, when some HBTs were formed by setting the design dimension of the lower limit Le of the emitter control layer 6 to 1.0 μm and 2.0 μm and the dimensions of the completed HBTs were measured, it was found that the lower limit Le of the emitter contact layer 6 has variations of about ±0.2 μm. The emitter contact layer 6 is formed by wet etching using the emitter electrode 7 as a mask. It is therefore considered that the lower limit Le of the completed emitter contact layer 6 has variations of about ±0.2 μm from the design dimension depending on the shape of the emitter electrode 7 as a mask and the wet etching conditions. Since the lower limit Le of the emitter contact layer 6 shown in FIG. 6 is the design dimension, for example, in the case of setting the lower limit Le to 1.0 μm, h_{FE} decrease ratios of HBTs formed with variations of about 0.8 to 1.2 μm in completion dimension are also plotted.

Therefore, in the embodiment, the design dimension of the lower limit Le of the emitter contact layer 6 is set to about 1.4 μm in consideration of variations so that the completion dimension of the lower limit Le of the emitter contact layer 6 becomes about 1.2 μm. Consequently, an HBT in which the lower limit Le of the emitter contact layer 6 on completion as an optimum value at which decrease in h_{FE} at the time of low current can be suppressed is about 1.2 μm can be formed.

Thus, a semiconductor device including the HBT of the invention is characterized in that the lower limit Le of the emitter contact layer 6 on completion is 1.2 μm or larger. Consequently, increase in the h_{FE} decrease ratio at the time of low current (in the embodiment, when Ic=10⁻⁶ A) in continuous operation of the HBT can be suppressed, and reliability of the HBT can be improved. That is, the invention can improve the characteristics of the HBT.

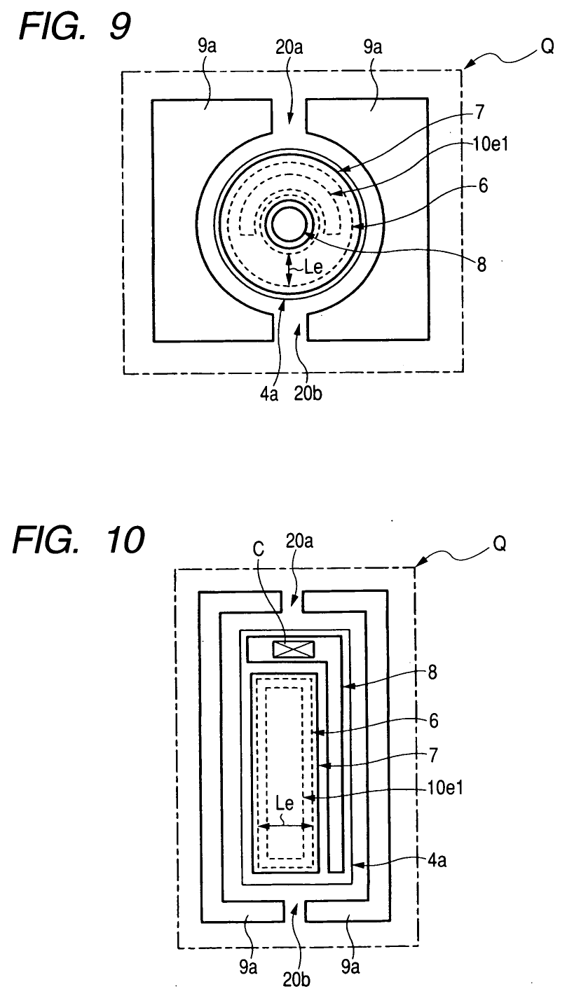

As described above, as long as an HBT (Q) in which the lower limit Le of the emitter contact layer 6 on completion is about 1.2 μm or larger is used, the plane shape of the emitter contact layer 6 may be an annular shape as shown in FIG. 9. Alternately, the plane shape of the emitter contact layer 6 may be a rectangular shape. As modifications, the plane shape of the emitter contact layer 6 may be a U shape or a C shape. It is therefore understood that when the lower limit Le of the emitter contact layer 6 in the HBT(Q) is about 1.2 μm or larger on completion, increase in the h_{FE} decrease ratio at the time of low current in the continuous operation of the HBT(Q) can be suppressed and reliability of the HBT improves.

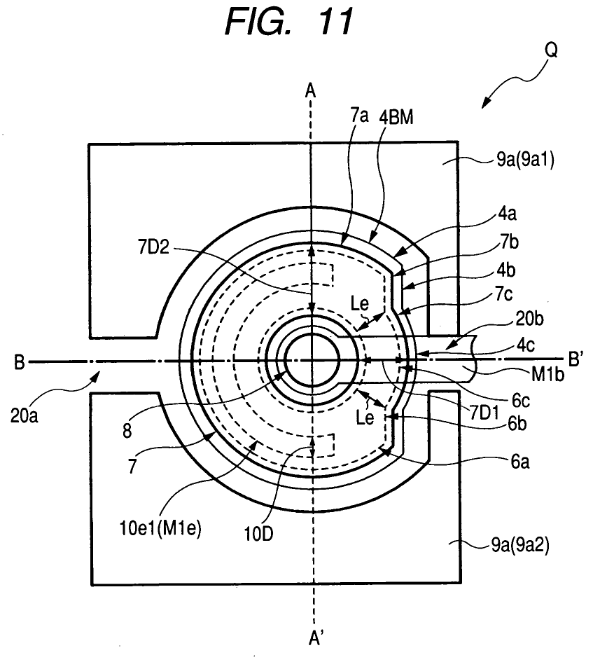

In the HBT(Q) shown in FIG. 10, different from the contact hole 10e1 formed in part of the annular-shaped emitter electrode 7, specifically, along the arc 7a in an HBT(Q) as shown in FIG. 1, the contact hole 10e1 for the emitter of the HBT(Q) shown in FIG. 10 can be formed on almost the entire surface of the emitter electrode 7. Consequently, in the HBT(Q) shown in FIG. 10, heat generated from the emitter region in the operation can be uniformly dissipated from the emitter lead line M1e formed in the contact hole 10e1. C indicates a contact portion on the base electrode 8.

In the HBT(Q) shown in FIG. 9, the plane shape of the base mesa 4BM can be made similar to that of the emitter electrode 7 and the plane shape of the base mesa 4BM can be made circular by using photolithography and wet etching techniques as the forming method, so that an effect of decreasing a base/collector junction area ratio can be produced.

With respect to the annular-shaped emitter contact layer 6 shown in FIG. 9 formed with the lower limit Le of about 1.2 μm on completion, the following has to be considered. In the case of forming the emitter contact layer 6, wet etching using the emitter electrode 7 as a mask is performed. For the wet etching, some electrode area of the emitter electrode 7 has to be assured. Specifically, as shown in FIG. 1, a region allowing the lower limit of the dimension 10D of the contact hole 10e1 in which the emitter lead line M1e to be connected to the emitter electrode 7 and variations has to be assured on the emitter electrode 7. On the emitter electrode 7 shown in FIG. 1, on assumption that the dimension 7D2 of the width of the annular shape including the arc 7a in which the contact hole 10e1 is formed is 4.0 μm, the region for forming the contact hole 10e1 whose dimension 10D is equal to or larger than the minimum processing dimension is assured. On the other hand, to form the emitter contact layer 6 whose lower limit Le that is about 1.4 μm in design dimension (1.2 μm in completion dimension) or larger, the dimension 7D1 of the projection 7c in the emitter electrode 7 shown in FIG. 1 is set to, for example, 2.0 μm. Since the emitter contact layer 6 is etched by using the emitter electrode 7 having the dimension 7D1 of 2.0 μm as a mask, the lower limit Le of the emitter contact layer 6 on completion is reduced to 1.8 μm. Consequently, the design dimension of the lower limit Le of the emitter contact layer 6 is set to 1.4 μm or larger so that the dimension on completion becomes 1.2 μm or larger.

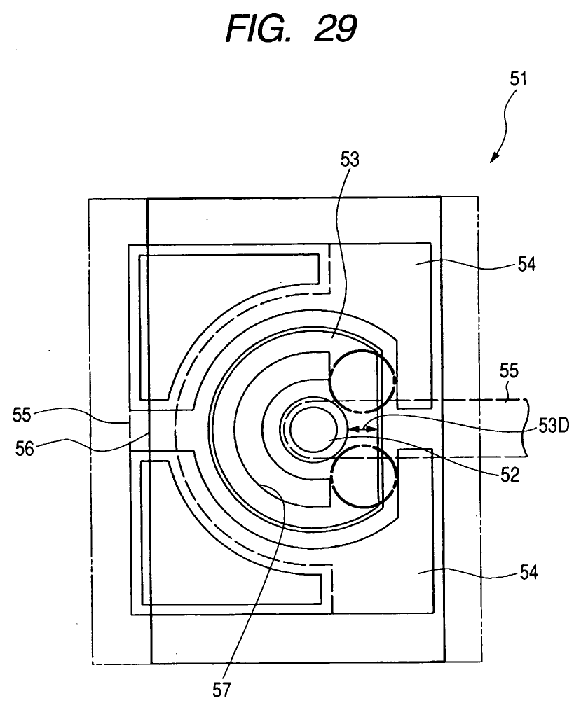

The case where the design dimension of the lower limit Le of the emitter contact layer 6 is set to, for example, 1.4 μm and that of the dimension 7D1 of the emitter electrode 7 is set to, for example, 2.0 μm in both of the HBTs (Q) shown in FIGS. 1 and 4 will be described below. In the HBTs(Q) shown in FIGS. 1 and 4, as described above, the lower limit Le of the emitter contact layer 6 on completion becomes about 1.2 μm or larger, so that decrease in h_{FE} at the time of low current can be suppressed. Moreover, the area that allows the lower limit of the dimension 10D of the contact hole 10e1 in which the emitter lead line M1e to be connected to the emitter electrode 7 is formed and variations is assured on the emitter electrode 7 of each of the HBTs(Q). In such a case, in the HBT(Q) shown in FIG. 1, the area of the emitter contact layer 6 is smaller than that in the HBT(Q) shown in FIG. 4 for the following reason. Different from the HBT(Q) in which the periphery of the emitter contact layer 6 shown in FIG. 4 has the plane shape constructed by the arc 6a and the chord 6b, the periphery of the emitter contact layer 6 shown in FIG. 6 has the plan shape in which the emitter contact layer 6 in the region where the arc 6a and the chord 6b cross each other is removed, that is, the plane shape constructed by the arc 6a, the chord 6b, and the projection 6c connected to the chord 6b. The region where the arc 6a and the chord 6b of the emitter contact layer 6 shown in FIG. 4 cross each other corresponds to a region where the temperature of the emitter electrode 53 locally increases during operation of the HBT 51 (particularly, the regions surrounded by the relatively-thick long and short dash lines) described in the background of the invention with reference to FIG. 29. By eliminating the region in which the temperature locally rises, that is, the area of the emitter region as the source of heat generation, the HBT(Q) shown in FIG. 1 produces the effect of suppressing heat generated from the emitter region during its operation more than the HBT(Q) shown in FIG. 4.

By constructing the plane shape of the periphery of the emitter contact layer 6 in the HBT(Q) shown in FIG. 1 by the arc 6a, the chord 6b, and the projection 6c connected to the chord 6b, heat generated from the emitter region during operation of the HBT(Q) can be reduced. In addition, the lower limit Le of the emitter contact layer 6 can be set to about 1.2 μm or larger on completion, so that reduction in h_{FE} in low-current operation of the HBT(Q) can be suppressed.

The projection 6c shown in FIG. 1 has a trapezoid shape whose bottom side is the chord 6b side. The shape is not limited to the trapezoid shape but may be a polygonal shape or an arc shape. FIG. 11 shows a plane shape of the HBT(Q) in which the projection 6c has an arc shape. The plane shape of the portion having the lower limit Le of the emitter contact layer 6 whose periphery is the arc-shaped projection 6c is a fan shape. When the lower limit Le of the HBT(Q) in FIG. 11 and that of the HBT(Q) in FIG. 1 are the same, the area of the emitter contact layer 6, that is, the area of the emitter region in the HBT(Q) having the arc-shaped projection 6c as shown in FIG. 11 is slightly smaller than that in the HBT(Q) having the trapezoidal projection 6c as shown in FIG. 1. Therefore, heat generated from the emitter region during operation can be reduced in the HBT(Q) shown in FIG. 11 more than that in the HBT(Q) shown in FIG. 1. The plane shape of the emitter contact layer 6 shown in FIG. 11 is obtained by adding an almost annular shape (C shape) larger than the annular shape having the width of the lower limit Le shown in FIG. 9 to the annular shape shown in FIG. 9.

A semiconductor device including the HBT(Q) described in the embodiment with reference to, for example, FIG. 1 will now be described in accordance with its manufacturing processes.

As shown in FIG. 12, the sub-collector layer 2 made of n⁺-type GaAs is grown by about 700 nm on the substrate 1 made of semi-insulating GaAs and having a thickness of about 600 μm by metal organic chemical vapor deposition (MOCVD). On the sub-collector layer 2, the collector layer 3 made of n-type GaAs and having a thickness of about 700 nm and the base layer 4 made of p-type GaAs and having a thickness of about 100 nm are sequentially formed by MOCVD. Subsequently, the emitter layer 5 made of n-type InGaP or n-type AlGaAs and having a thickness of about 35 nm is deposited by MOCVD and, further, the emitter contact layer 6 having a thickness of 400 nm is formed. The emitter contact layer 6 is a stacked film of the n-type GaAs layer and the n-type InGaAs layer. The InGaAs layer in the emitter contact layer 6 is used to form ohmic contact with the emitter electrode 7 which will be described later. As described above, p-type GaAs is used for the base layer 4, and n-type InGaP is used for the emitter layer 5, thereby forming a hetero junction.

Subsequently, a tungsten silicide (WSi) film as an example of a conductive film is deposited to about 300 nm by, for example, sputtering. After that, the WSi film is processed by using photolithography and dry etching techniques to form the emitter electrode 7 and a back-side via electrode 7v.

The emitter electrode 7 is formed so that the plane shape of its periphery becomes an almost annular shape constructed by the arc 7a, the chord 7b, and the projection 7c connected to the chord 7b. Alternately, the emitter electrode 7 whose periphery has an almost annular shape constructed by the arc 7a and the chord 7b may be formed like the emitter electrode 7 in the HBT (Q) shown in FIG. 4.

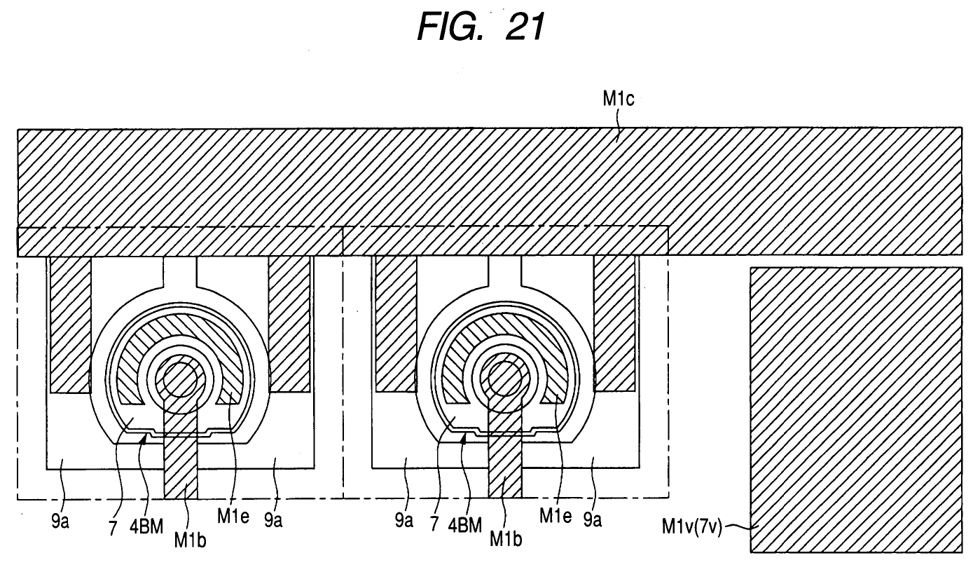

In FIG. 12, only one HBT formation region is shown. However, as shown in FIG. 21 to be described later, a block in which a plurality of HBTs are formed exists, and the back-side via electrode 7v is formed between blocks.

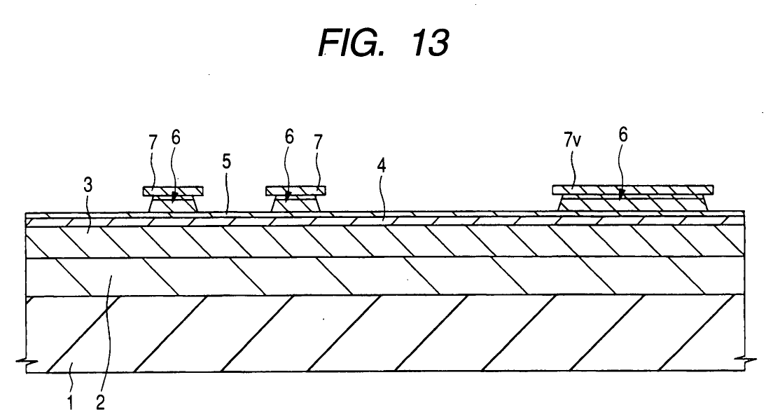

Subsequently, as shown in FIG. 13, the emitter contact layer 6 is subjected to wet etching using the emitter electrode 7 and the back-side via electrode 7v as a mask to expose the emitter layer 5. At this time, the emitter layer 5 may be etched to expose the base layer 4.

As shown in FIG. 1, the emitter contact layer 6 is formed so that the plane shape of the periphery of the emitter contact layer 6 becomes an almost annular shape constructed by the arc 6a, the chord 6b, and the projection 6c connected to the chord 6b. As described above, the emitter contact layer 6 is formed so that the lower limit Le (refer to FIG. 3) of the emitter contact layer 6 in a direction parallel with the main surface of the substrate 1 becomes 1.2 μm or larger. As described above, in the case where the HBT (Q) is operated, increase in the decrease ratio of the current amplification h_{FE} of the low current can be suppressed. The emitter contact layer 6 has the lower limit in the chord 6b or the projection 6c connected to the chord 6b, so that the heat generation from the emitter region below the emitter contact layer 6 just below the base lead line M1b can be lessened as described above. The emitter contact layer 6 whose periphery has an almost annular shape constructed by the arc 6a and the chord 6b may be also formed like the emitter contact layer 6 in the HBT(Q) shown in FIG. 4.

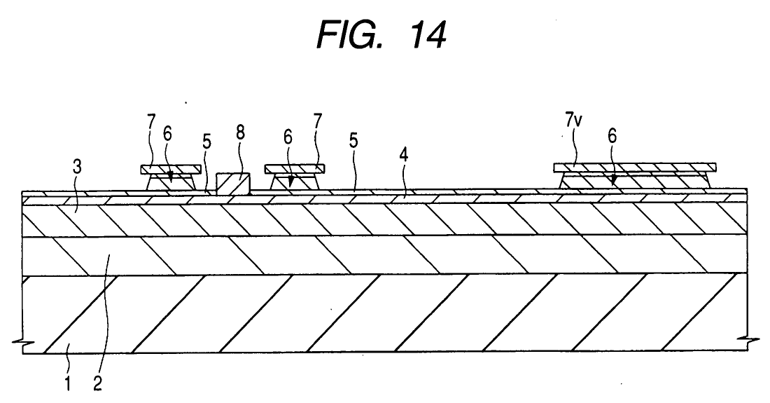

Subsequently, as shown in FIG. 14, the base electrode 8 as a stack film obtained by stacking platinum (Pt), titanium (Ti), molybdenum (Mo), Ti and gold (Au) in order is formed. The thickness is, for example, about 300 nm. The base electrode 8 can be formed by, for example, the lift-off method. After that, by performing heat treatment (alloy process), the lowest layer of Pt in the base electrode 8, the emitter layer 5 made of n-type InGaP, and the base layer 4 made of p-type GaAs are made react. By the reactive part, ohmic contact can be formed between the base electrode 8 and the base layer 4.

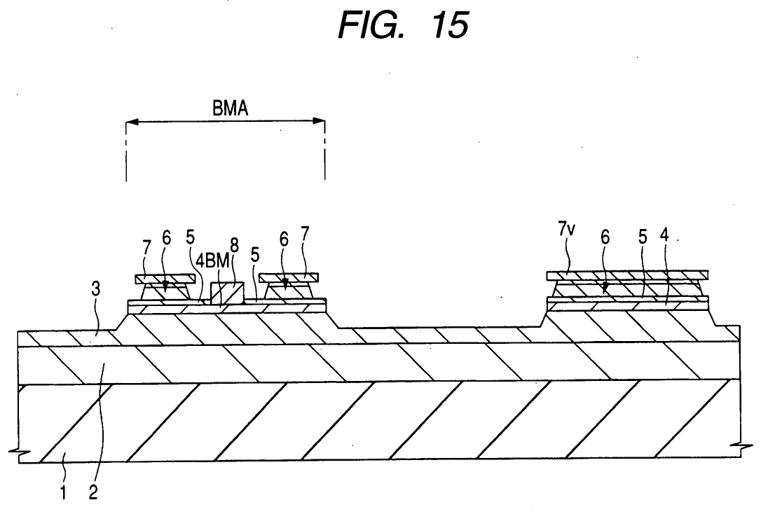

After that, as shown in FIG. 15, the emitter layer 5 and the base layer 4 are etched by using photolithography and wet etching techniques to form the base mesa 4BM. BMA in the diagram shows a region in which the base mesa 4BM is formed. As etchant, for example, a mixed solution of phosphoric acid and hydrogen peroxide is used. By the etching, the emitter layer 5 and the base mesa 4BM are separated transistor by transistor.

The base mesa 4BM (base layer 4) is formed so that the plane shape of the periphery becomes an almost circular shape constructed by the arc 4a, the chord 4b, and the projection 4c connected to the chord 4b. Similarly, the emitter layer 5 is formed so that the plane shape of the periphery becomes an almost annular shape constructed by the arch, the chord, and the projection connected to the chord. The base electrode 8 is formed in the center of the emitter layer 5, and the region other than the center portion (base electrode 8) becomes a pn junction between the emitter layer 5 and the base layer 4 (base mesa 4BM). Alternately, the base mesa 4BM (base layer 4) having an almost circular shape whose periphery has an almost circular shape constructed by the arc 4a and the chord 4b may be formed like the base mesa 4BM (base layer 4) in the HBT(Q) shown in FIG. 4. Similarly, the emitter layer 5 whose periphery has an almost annular shape constructed by an arc and a chord may be formed.

From the viewpoint of high frequency characteristics, the smaller junction capacitance of the base layer and the collector layer is preferable with respect to the same area of the emitter layer. That is, the smaller region of forming the base mesa relative to the same area of the emitter layer is preferable.

Therefore, by forming the base mesa 4BM in a size almost the same as the periphery of the emitter layer 5 like in the embodiment, the formation region BMA of the base mesa 4BM can be reduced relative to the emitter layer 5, and the junction capacitance can be reduced.

The base electrode 8 is positioned above a center portion of the base mesa 4BM, and the emitter electrode 7 and the emitter contact layer 6 are positioned in the peripheral portion of the base electrode 8 above the base mesa 4BM. At the time of forming the base mesa 4BM, the emitter layer 5 and the base layer 4 around the back-side via electrode 7v are also etched. Further, at the time of etching the base layer 4 and the like, the collector layer 3 below the base layer 4 is etched by about 300 nm.

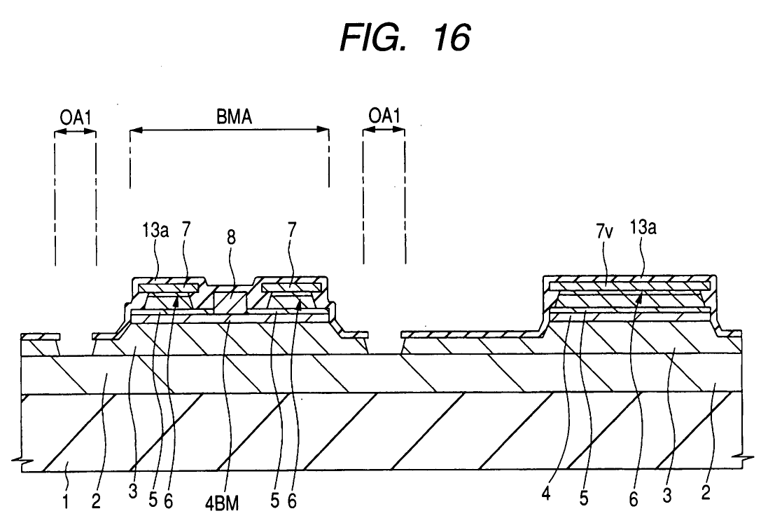

As shown in FIG. 16, an insulating film for example, (silicon oxide film) 13a is deposited to about 100 nm on the substrate 1. The insulating film 13a is formed so as to protect the base electrode 8 but can be omitted. Subsequently, by selectively etching the insulating film 13a and the collector layer 3, part of the sub-collector layer 2 is exposed. The exposed region is called a region OA1.

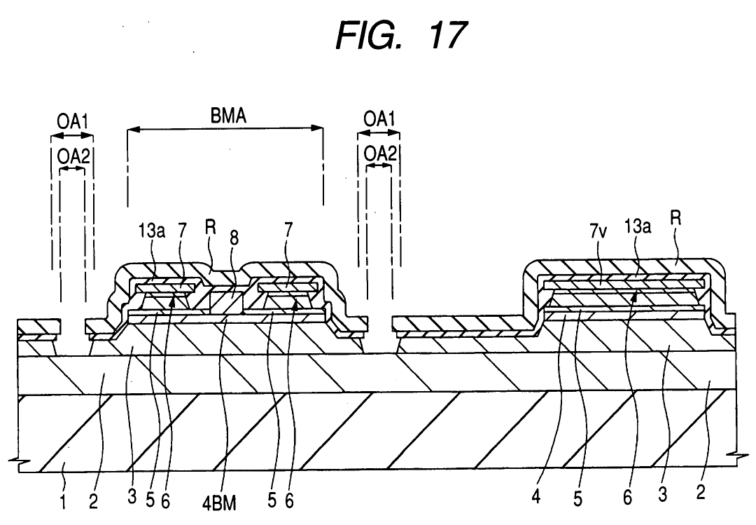

Subsequently, as shown in FIG. 17, a photoresist film (hereinbelow, simply called “resist film”) R is formed on the entire surface of the substrate 1. The resist film R on the region OA1 is removed by a photolithography process. As a result, the sub-collector layer 2 in the region OA1 is exposed. An opening OA2 in the resist film R is formed to be smaller than the region OA1. In other words, the resist film R overhangs from the end of the insulating film 13a and the collector layer 3 as lower layers. The resist film R may have an inverted taper shape.

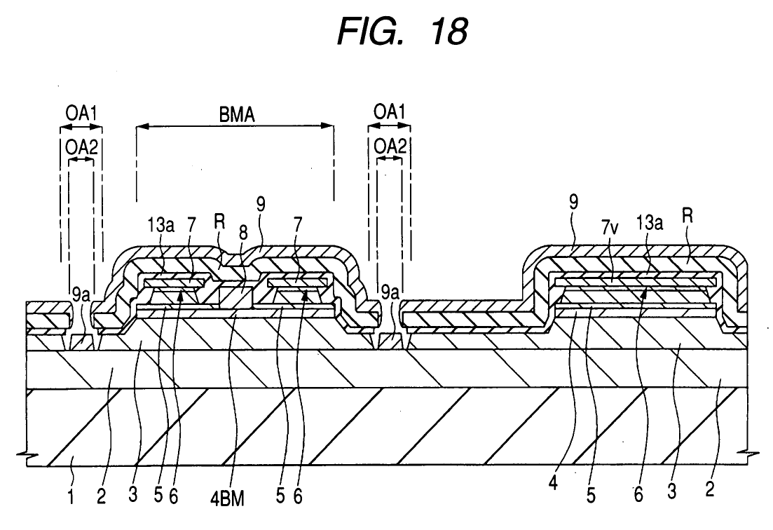

Subsequently, as shown in FIG. 18, gold germanium (AuGe), nickel (Ni), and Au are formed in order on the entire surface of the substrate 1, thereby forming the stack films 9 and 9a. As shown in the diagram, the stacked films 9 and 9a are formed on the resist film R and in the opening OA2. Since the resist film R is formed so as to overhang, the stack film 9 is not deposited on side walls of the insulating film 13a and the collector layer 3. The under face of the resist film R is exposed from the end of the insulating film 13a.

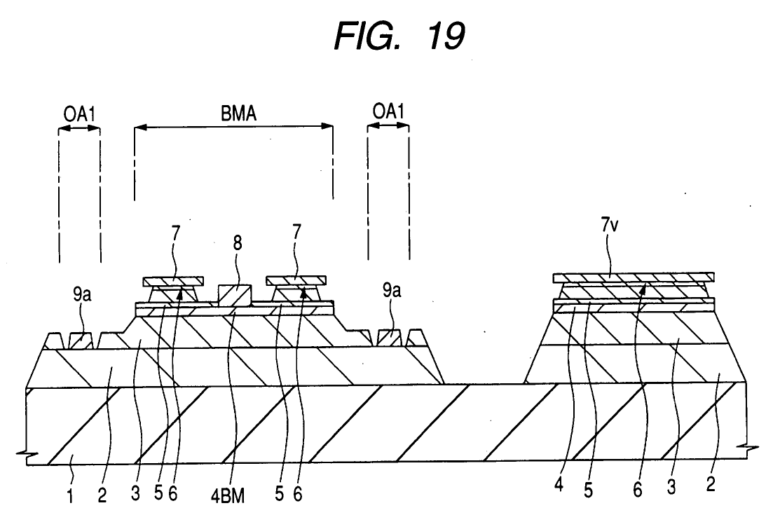

As shown in FIG. 19, the resist film R is removed by a stripping agent (etchant). In this operation, the stripping agent enters from the exposed portion in the under face of the resist film R and dissolves the resist film R. After the resist film R is removed, the stack film 9 is also peeled off, and only the stack film 9a remains in the opening OA2 (on the region OA1), thereby becoming the collector electrode 9a. In the embodiment, as shown in FIG. 1, two notches 20a and 20b are provided in the shape of the collector electrode 9a. The notches 20a and 20b can be also said as connection parts of the resist film R (stack film 9). Specifically, the resist film R (stack film 9) is formed also on the connection part between the periphery of the region OA1 and the region in which the base mesa 4BM is formed and, as a result, the notches 20a and 20b are formed. The collector electrode 9a is separated by the notches 20a and 20b, thereby obtaining two shapes of the first part 9a1 and the second part 9a2. By providing one of the two notches 20a and 20b on the projection side of the region of the base mesa 4BM, the base lead line M1b to be described later can be easily formed. Moreover, the parasitic capacitance between the base lead line M1b and the collector lead line M1c (collector electrode 9a) can be reduced.

Subsequently, as shown in FIG. 19, the insulating layer 13a is removed, and the collector layer 3 and the sub-collector layer 2 on the outside of the collector electrode 9a are etched, thereby electrically isolating the transistors. At this time, the collector layer 3 and the sub-collector layer 2 around the back-side via electrode 7v are also removed. The transistors can be isolated also by doping the sub-collector layer 2 on the outside of the collector electrode 9a with p-type impurity (pn junction isolation).

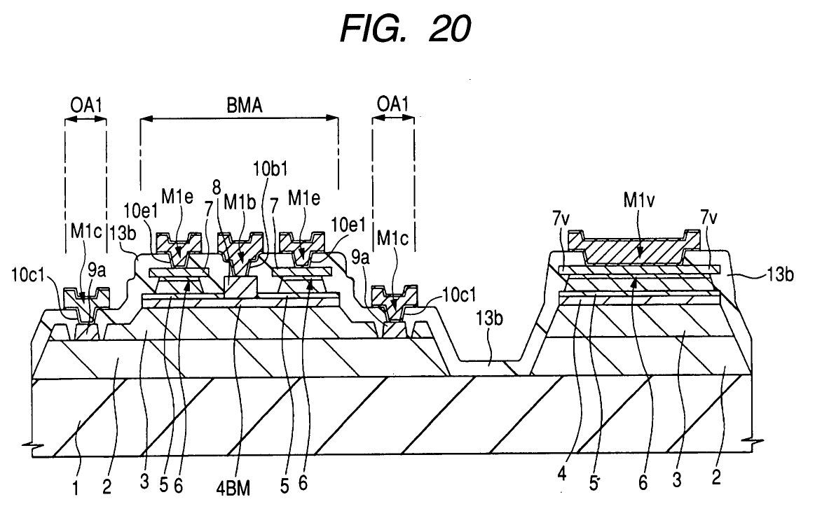

After that, as shown in FIG. 20, the insulating film (interlayer insulating film) 13b such as a silicon oxide film is deposited on the substrate 1 by CVD. It is also possible to form the insulating film 13b on the insulating film 13a by performing etching for isolation on the collector layer 3 and the sub-collector layer 2 while leaving the insulating film 13a.

Subsequently, by removing the insulating film 13b on the emitter electrode 7, the base electrode 8, and the collector electrode 9a, contact holes 10e1, 10b1, and 10c1 are formed. After that, a stack film of, for example, molybdenum (Mo), Au, and Mo (hereinbelow, called “Mo/Au/Mo film”) is deposited as a conductive film on the insulating film 13b and also in the contact holes 10e1, 10b1, and 10c1. Subsequently, by etching the Mo/Au/Mo film, the emitter lead line M1e, the base lead line M1b, and the collector lead line M1c are formed. At this time, a line M1v is formed on the back-side via electrode 7v. Those lines serve as first layer lines formed in the same line layer. As shown in FIG. 1, the base lead line M1b is formed so as to pass above the chord 7b of the emitter electrode 7 or the projection 7c connected to the chord 7b. FIG. 21 is a plan view of a main part after formation of the first layer lines.

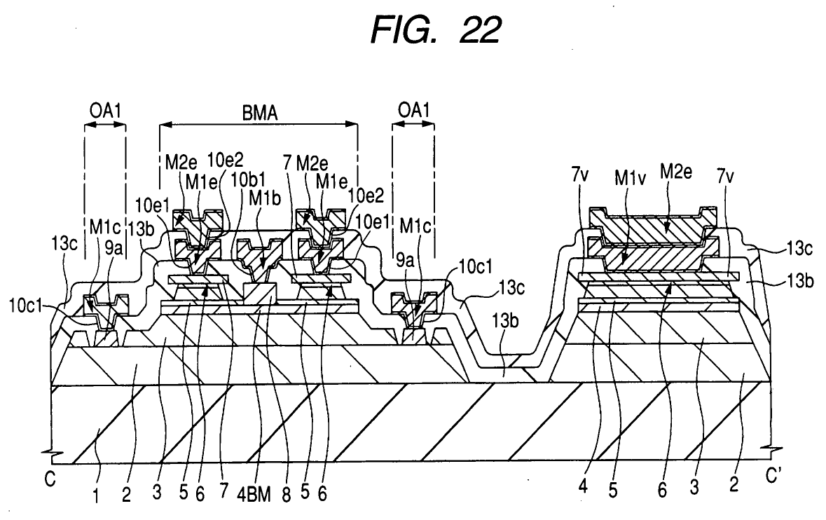

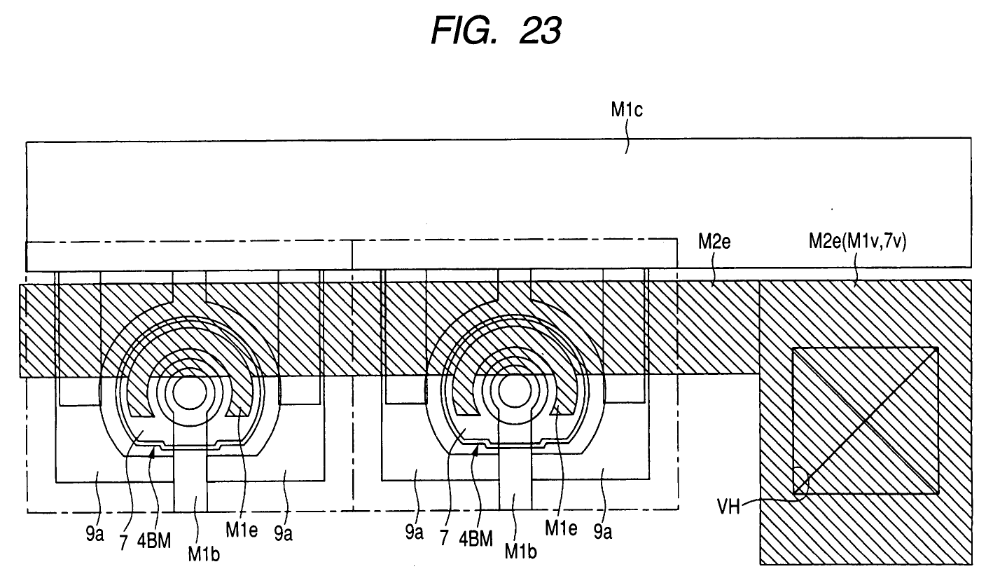

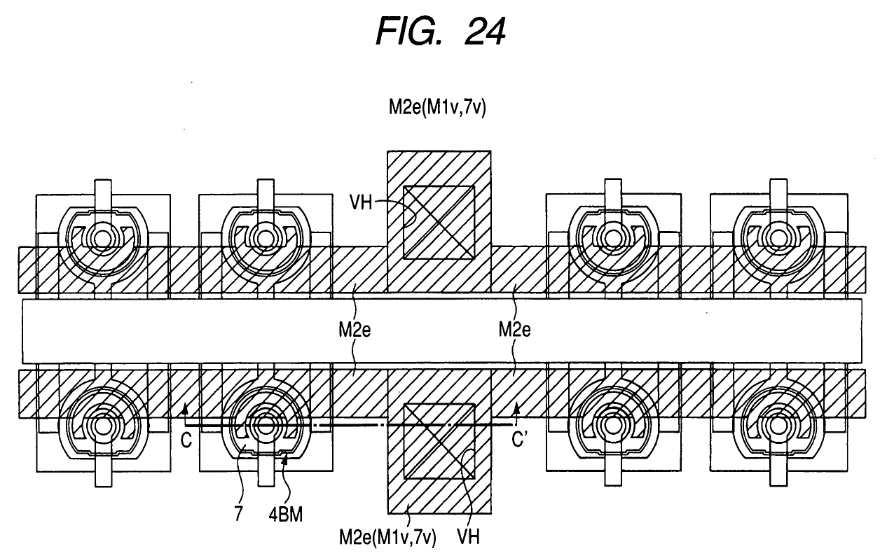

As shown in FIG. 22, the insulating film (interlayer insulating film) 13c such as a silicon oxide film is deposited on the substrate 1 by, for example, CVD so as to cover the first layer lines such as the emitter lead line M1e. Subsequently, the insulating film 13c on the emitter lead line M1e is removed to form a contact hole 10e2. For example, the Mo/Au/Mo film is deposited as a conductive film on the insulating film 13c including the contact hole 10e2. After that, by etching the Mo/Au/Mo film, the emitter lead line (second layer line) M2e is formed. FIGS. 23 and 24 are plan views of a main part after the second layer line is formed. As shown in the diagram, the emitter lead line M2e extends to a position above the back-side via electrode 7v. FIG. 22 is a cross section taken along line C-C′ of FIG. 24. The emitter lead line M2e may be widened to cover the emitter lead line M1e. VH denotes a via hole to be described later.

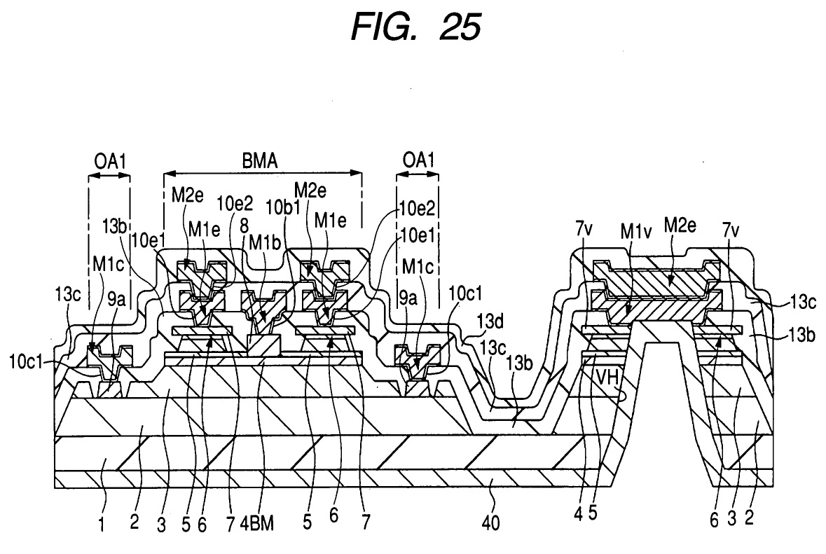

As shown in FIG. 25, the insulating film (interlayer insulating film) 13d such as a silicon oxide film is deposited on the substrate 1 so as to cover the emitter lead line M2e. Subsequently, a resistive element, a capacitive element, or the like is formed as necessary in a not-shown region on the substrate 1, and the surface of the substrate 1 is covered with a protection film.

The protection filmside (device formation surface) is set as the bottom side and the back side of the substrate 1 is polished so that its thickness becomes 70 to 100 μm. A not-shown resist film is used as a mask and the substrate 1, the sub-collector layer 2, the collector layer 3, the base layer 4, the emitter layer 5, and the emitter contact layer 6 on the first layer line M1v are etched, thereby forming the via hole VH. The etching is, for example, dry etching. After that, a deposit generated at the time of the dry etching is removed by a wet process. For the wet process, for example, a mixture of ammonia and hydrogen peroxide is used.

By using the first layer line M1v as an etching stopper, the back-side via electrode (WSi) 7v is also etched. Mo positioned in the lower layer in the first layer line (Mo/Au/Mo film) is also etched. Therefore, the back-side via electrode (WSi) 7v and Mo are positioned annularly around the via hole VH. In other words, the stack film of the back-side via electrode (WSi) 7v and Mo remains on the side of the via hole VH.

A metal film is formed by using Au on the back side of the substrate 1 including the inside of the via hole VH by, for example, plating, and the back-side electrode 40 is formed. Since the back-side electrode 40 is in contact with the portion of Au constructing the first layer line M1v, contact resistance is reduced. Since Au itself is a low-resistance material, it is preferably used for a line (in this case, M1v and M2e) for connection to the back-side electrode 40. Alternately, Au/Mo/Wsi, Au/Pt/Ti, or the like can be used for the lines.

By the above operations, a semiconductor device in which a plurality of HBT(Q)s, resistive element, capacitive element, and via hole VH are formed is completed.

### Second Embodiment

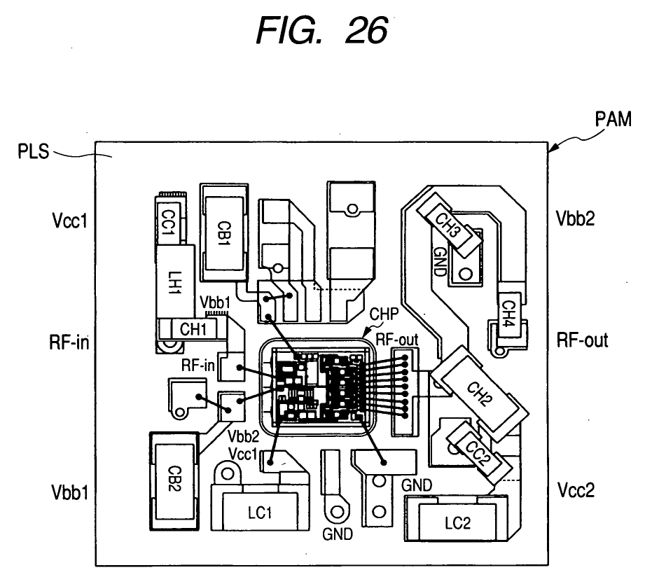

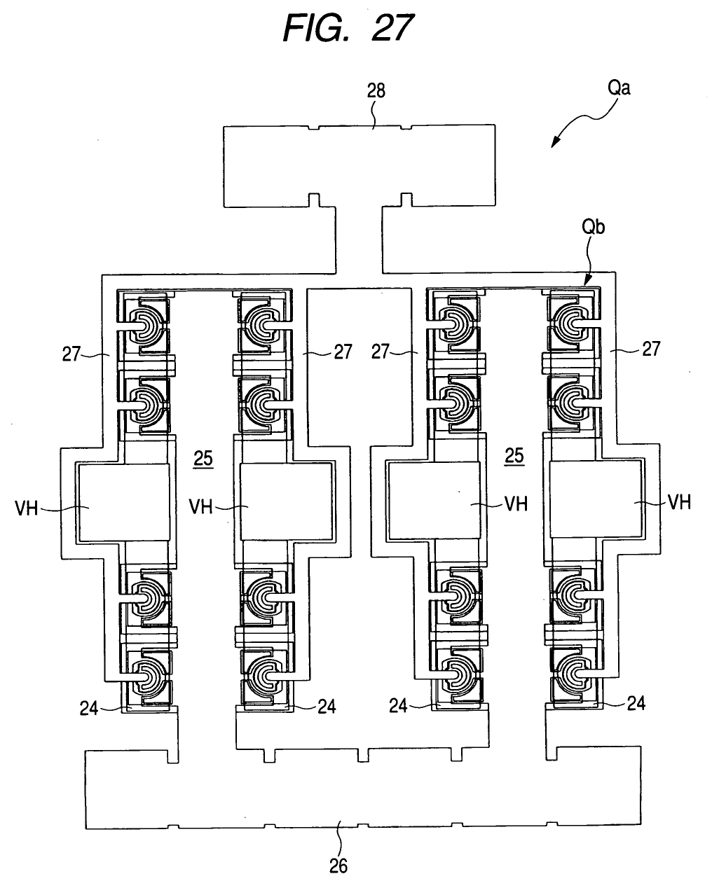

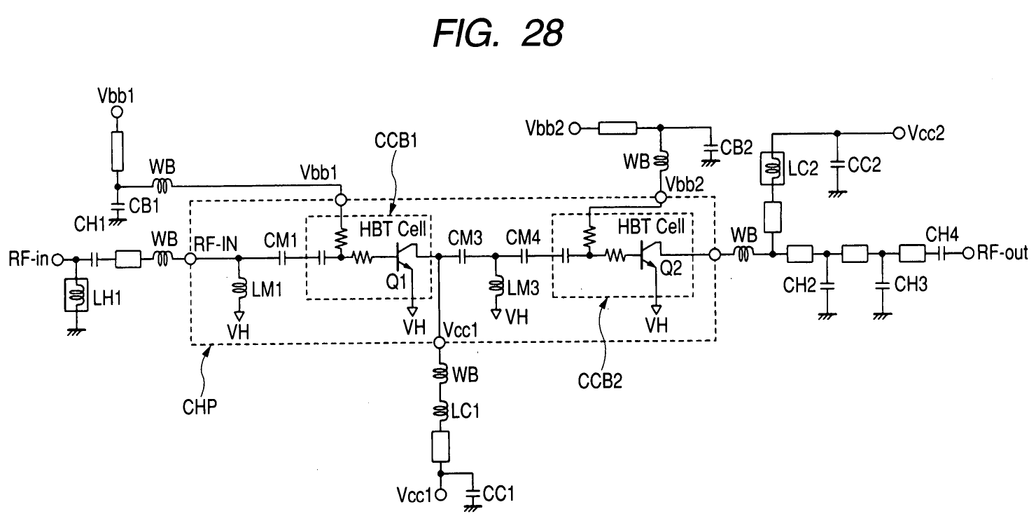

In a second embodiment, an example of an electronic device including a power amplifier having one or a plurality of hetero-junction bipolar transistors (HBTs) in the first embodiment will be described by using a power amplifier module with reference to FIGS. 26 to 28. FIG. 26 is a plan view of a main part of a power amplifier module PAM of the second embodiment. FIG. 27 is a plan view of a main part of a semiconductor chip (hereinbelow, simply called the chip) constructing the power amplifier module PAM. FIG. 28 is a circuit diagram of a main part of the power amplifier module PAM.

The power amplifier module PAM of the second embodiment has an operating frequency of about 500 MHz or higher and is a power amplifier module PAM of the GSM (Global System for Mobile Communication) in which the operating frequency is about 800 MHz to 900 MHz, the DCS (Digital Cellular System) in which the operating frequency is about 1.8 GHz to 1.9 GHz), or a system corresponding to both of the GSM and DCS.

As shown in FIG. 26, on a wiring board PLS of the power amplifier module PAM, a chip CHP, capacitive elements CB1, CB2, CC1, CC2, CH1, CH2, CH3, and CH4, inductors LC1, LC2, and LH1, and the like are mounted. The capacitive elements CB1, CB2, CC1, CC2, CH1, CH2, CH3, and CH4, and the inductors LC1, LC2, and LH1 are individual chips directly mounted on the wiring board PLS by, for example, face-down bonding.

As shown in FIG. 27, in an HBT (Qa) for the amplification stage, a plurality of basic HBTs (Qb) which are basic HBTs (Q) shown in FIG. 1 are arranged in parallel. Therefore, in the basic HBT(Qb), the periphery of the base layer and the emitter contact layer has a plane shape constructed by the arc, the chord, and the projection connected to the chord.

In FIG. 27, the number of basic HBTs (Qb) is 16. An HBT for an amplification stage having a layout using a larger number of basic HBTs (Qb) can be also used. Generally, an HBT for an amplification stage is constructed by about 30 to 100 basic HBTs. On the chip CHP, in addition to the plurality of HBTs, resistive elements, capacitive elements, inductors, and the like are formed.

In the basic HBT(Qb), one via hole VH is disposed for each line. The emitter electrode of the basic HBT(Qb) is connected to the via hole VH via an emitter combining line 24 constructed by the second layer line. The collector electrode of the basic HBT (Qb) is connected to a collector output terminal pad 26 via a collector combining line 25 constructed by the first layer line, and the base electrode of the basic HBT(Qb) is connected to a base input terminal pad 28 via a base combining line 27 constructed by the first layer line.

As shown in FIG. 28, external electrode terminals in the power amplifier module PAM are an input terminal RF-in, an output terminal RF-out, reference potentials (power source potentials) Vcc1 and Vcc2, and bias terminals Vbb1 and Vbb2.

Between RF-in and RF-out, two amplification stages are cascaded. First and second amplification stages are formed by a first circuit block CCB1 and a second circuit block CCB2, respectively. In the first and second circuit blocks CCB1 and CCB2, an HBT (Q1) and an HBT (Q2) are formed, respectively. In the embodiment, an example of the power amplifier module PAM using two amplification stages is shown. Alternately, a number of amplification stages may be used. For example, when three amplification stages are used, the case of applying HBTs to all of the three amplification stages or the case of applying MIS transistors to the first and second amplification stages and applying an HBT to the third amplification stage may be employed.

The RF-in is electrically connected to the base electrode of the HBT (Q1) included in the first circuit block CCB1 via a predetermined inter-stage matching circuit. By the HBT(Q1), high frequency power is amplified. The inter-stage matching circuit is formed by a capacitive element CM1 and an inductor LM1 as passive parts (passive elements). Since an amplification system has a two-stage configuration, the base electrode of the HBT (Q2) included in the second circuit block CCB2 as the second amplification stage is connected to the collector electrode of the HBT (Q1) in the pre-stage via a predetermined inter-stage matching circuit. The inter-stage matching circuit disposed between the HBT(Q1) and the HBT(Q2) is formed by capacitive elements CM3 and CM4 and an inductor LM3 as passive parts (passive elements).

The electronic device of the second embodiment includes the power amplifier constructed by the HBTs of the first embodiment and can operate without decreasing h_{FE} of the HBT at the time of low current, so that the power gain can be improved.

The invention achieved by the inventors herein has been described concretely above on the basis of the embodiments. Obviously, the invention is not limited to the foregoing embodiments but can be variously changed without departing from the gist.

For example, in the first embodiment, an emitter electrode is used as a mask for forming an emitter contact layer (emitter mesa). However, when the lower limit is 1.2 μm or larger on completion, wet etching using a photoresist film or the like can be performed. In such a case, even when the lower limit of the emitter electrode is, for example, 1.0 μm or, further, 0 μm (the case where there is no emitter electrode is also possible), it is sufficient if the lower limit on completion becomes 1.2 μm or larger by setting the design lower limit of the emitter contact layer to 1.4 μm or larger.

The present invention is widely used in the manufacturing industry that manufactures semiconductor devices.

1. A semiconductor device including a bipolar transistor comprising:
a substrate made of a compound semiconductor;
a collector layer formed over a main surface of the substrate;
a base layer formed over the collector layer;
an emitter layer formed over the base layer;
a collector electrode electrically connected to the collector layer;
a base electrode electrically connected to the base layer;
an emitter contact layer formed on the emitter layer and electrically connected to the emitter layer; and
an emitter electrode electrically connected to the emitter contact layer,
wherein a plane shape of the base layer is an almost circular shape in a plane parallel with the main surface of the substrate,
wherein a plane shape of the emitter layer, the emitter contact layer, and the emitter electrode is an almost annular shape surrounding the base electrode in a plane parallel with the main surface of the substrate, and
wherein lower limit of the emitter contact layer is 1.2 μm or larger in a direction parallel with the main surface of the substrate.

2. A semiconductor device according to claim 1, wherein the periphery of the base layer and the emitter contact layer has a plane shape comprised of an arc, a chord, and a projection connected to the chord in a plane parallel with the main surface of the substrate.

3. A semiconductor device according to claim 1, wherein the periphery of the base layer, the emitter layer, the emitter contact layer, and the emitter electrode has a plane shape comprised of an arc and a chord in a plane parallel with the main surface of the substrate.

4. A semiconductor device according to claim 3, further comprising:
an interlayer insulating film formed on the emitter electrode and the base electrode;
an emitter contact hole and a base contact hole formed in the interlayer insulating film; and
an emitter lead line and a base lead line electrically connected to the emitter electrode and the base electrode via the emitter contact hole and the base contact hole, respectively,
wherein the emitter contact hole is formed in the periphery of the base contact hole, and
wherein the emitter contact hole is formed along an arc portion of the emitter electrode.

5. A semiconductor device according to claim 4, wherein the base lead line extends so as to pass above a chord portion of the emitter electrode.

6. A semiconductor device according to claim 4, wherein the emitter lead line and the base lead line are comprised of the same wiring layer.

7. A semiconductor device according to claim 1, wherein the substrate is made of GaAs, and the emitter layer is made of InGaP or AlGaAs.

8. An electronic device including a power amplifier,
wherein the power amplifier is comprised of one or more bipolar transistors,
wherein the bipolar transistor comprises:
a substrate made of a compound semiconductor;
a collector layer formed over a main surface of the substrate;
a base layer formed over the collector layer;
an emitter layer formed over the base layer;
a collector electrode electrically connected to the collector layer;
a base electrode electrically connected to the base layer;
an emitter contact layer formed on the emitter layer and electrically connected to the emitter layer; and
an emitter electrode electrically connected to the emitter contact layer,
wherein a plane shape of the base layer is an almost circular shape in a plane parallel with the main surface of the substrate,
wherein a plane shape of the emitter layer, the emitter contact layer, and the emitter electrode is an almost annular shape surrounding the base electrode in a plane parallel with the main surface of the substrate, and
wherein lower limit of the emitter contact layer is 1.2 μm or larger in a direction parallel with the main surface of the substrate.

9. An electronic device according to claim 8, wherein the electronic device is mounted over wireless communication equipment, and operating frequency of the power amplifier is 500 MHz or higher.

10. An electronic device according to claim 8, wherein the power amplifier is constructed by connecting a plurality of bipolar transistors in multiple stages, and passive parts for a matching circuit are connected between the bipolar transistors.

11. An electronic device according to claim 8, wherein the periphery of the base layer and the emitter contact layer has a plane shape comprised of an arc, a chord, and a projection connected to the chord in a plane parallel with the main surface of the substrate.

12.-18. (canceled)
